(19) United States
(12) Patent Application Publication
(10) Pub. No.: US 2026/0155536 A1
(43) Pub. Date: Jun. 4, 2026

(54) VEHICLE ELECTRIC BATTERY

(71) Applicant: CAPACITE, BORDEAUX (FR)

(72) Inventor: Alexandre Emile Albert VALLETTE, BORDEAUX (FR)

(21) Appl. No.: 18/723,975

(22) PCT Filed: Dec. 26, 2022
(86) PCT No.: PCT/EP2022/087845

§ 371 Date: Aug. 16, 2024

(30) Foreign Application Priority Data
Dec. 31, 2021 (FR) FR2114726

(51) Int. Cl. H01M 50/519; H01M 10/42; H01M 50/213; H01M 50/249; H05K 1/14

(52) U.S. Cl. CPC H01M 50/519; H01M 10/4257; H01M 50/213; H01M 50/249; H05K 1/144; H01M 2010/4271; H01M 2220/20; H05K 2201/042; H05K 2201/09027; H05K 2201/10037

(57) ABSTRACT

The invention relates to an electric battery (1, 10), comprising: a plurality of electrical storage cells (2), at least a first printed circuit board (41) disposed against end faces (21, 22) of the cells and provided with a plurality of first electrical connection elements (43) with the cells; a second printed circuit board (5) supporting a control system (6) for the cells; characterized in that one of the first and second printed circuit boards has a first board edge connector (61) and in that the other of the first and second printed circuit boards has a connection portion (48) that inserts into said first board edge connector.

The invention relates to the field of electric batteries of vehicles. More specifically, the invention relates to the field of the electrical interconnection of the electrical storage cells of an electric battery.

Electric batteries, in particular in the case of electric vehicles, generally consist of an assembly of electrical storage cells, also known as accumulators. When interconnected, in series or in parallel, these accumulators can deliver electrical power, for example intended to electrically power the vehicle's equipment or its engine.

It is known to associate a management or control system for the battery, also known as a BMS (battery management system), with the electrical storage cells of a battery. This system conventionally performs the function of monitoring the state of the storage cells, and in particular their voltage, temperature, or state of charge (SOC).

This system can also perform functions of controlling the charging and/or discharging of the storage cells of the battery, for example in order to protect these cells against overvoltage or undervoltage during charging, or against overcurrent or significant temperature variations during charging or discharging.

This system can also perform a so-called balancing function of the storage cells. The electrical storage cells are intended to undergo a plurality of charging and discharging cycles. However, the dispersion of cell characteristics causes charging imbalances over the course of these cycles. Thus, in order to maintain the capacity of the battery whilst extending its life, it has thus been found to be necessary to balance the different cells making up the battery in such a way that they all have essentially the same state of charge and the same voltage level.

For the control system of the battery to be able to perform these different functions, it must be interconnected to the different cells of the battery. For this purpose, it is known to mount the control system of the battery on a printed circuit board which is equipped with a plurality of connecting wires or terminals that can thus be soldered to the terminals of each of the cells or to the terminals of groups of cells. However, this solution is not satisfactory as it entails a large number of soldering operations. Furthermore, once the battery has been assembled, these soldered connections make it complicated to dismantle the battery and prevent the printed circuit board from being separated from the storage cells. However, there is a need to be able to replace only the control system of the battery if it fails, or on the contrary to replace only used cells as part of a maintenance or reconditioning operation of the battery.

There is thus a need for a battery which is simple to assemble and recondition and wherein the electrical storage cells and the printed circuit board supporting the battery management system can be easily separated. The invention is set against this context and aims to meet this need.

For this purpose, the object of the invention is an electric battery, comprising:
a. a plurality of electrical storage cells, each cell having end faces located on opposite sides of the cell, each end face being provided with a contact terminal;
b. at least a first printed circuit board disposed perpendicular to the end faces located on one of the sides of the cells, the printed circuit board being provided with a plurality of first electrical connection elements, each of the first electrical connection elements being located opposite one of the contact terminals of the cells;
c. a second printed circuit board supporting a control system for the electrical storage cells.

The invention is characterized in that one of the first and second printed circuit boards has a first board edge connector and in that the other of the first and second printed circuit boards has a connection portion that inserts into said first board edge connector.

It is thus understood that the storage cells can be interconnected by means of a first printed circuit board and then connected to the control system of the battery by a second printed circuit board, these two boards being connected to each other by a board edge connector. In other words, cells can be interconnected without soldering, by means of simple and standard contact elements, which makes it possible to simplify the design of the battery, to reduce its cost, and to allow one or more cells to be replaced when used. Similarly, the use of a connector of the board-edge type allows the battery management system to be easily separated from the assembly of the storage cells without any risk of damaging them, which makes it possible for either of them to be replaced or repaired easily.

An “electrical storage cell” is understood to be an elementary, for example electrochemical, device for storing electricity, which can be discharged and charged. Each cell can be of the lithium type, for example lithium-ion or lithium-polymer. Each cell can, for example, have an overall cylindrical shape, the contact terminals being provided on each end face delimiting the cylinder, one of these terminals being a so-called positive terminal and the other being a negative terminal.

A “first printed circuit board” is understood to be a printed circuit board (PCB) provided with electrical traces interconnecting the connection elements. It can be provided that all the cells of the battery are interconnected in series or in parallel by means of the first printed circuit board, or that the cells are interconnected, by means of the first printed circuit board, to form groups of cells interconnected in series or in parallel, the groups being interconnected in series or in parallel by means of the first printed circuit board.

A “second printed circuit board” is understood to be a printed circuit board (PCB) on which an assembly of electronic components is mounted, forming the control system for the storage cells, and provided with electrical traces interconnecting the control system for the storage cells to the first board edge connector or to one or more output terminals provided on the connection portion.

Advantageously, it can be provided that the first board edge connector and the connection portion are arranged such that connection terminals provided on the connection portion are held in solder-free contact, when the connection portion is inserted into the first board edge connector, with connection pins of the first board edge connector. For example, the first board edge connector can have a plurality of pairs of connection pins, the connection pins of the same pair of pins facing each other and each of these pins of the same pair forming a spring, the restoring force of which is oriented toward the other of the pins of this pair.

Preferably, the first board edge connector and the connection portion can be arranged such that the first printed circuit board and the second printed circuit board extend at an angle to each other, in particular 90°, when the connection portion is inserted into the first board edge connector. For example, the first board edge connector can be arranged on a surface of the printed circuit board supporting it, which surface is identical to or opposite the surface of the printed circuit board supporting the control system for the electrical storage cells, and in particular at an edge of said surface. If required, the connection portion can protrude from an edge of the printed circuit board which comprises it, whilst being coplanar with the rest of this board.

A control system for the electrical storage cells is understood to be a system capable of performing one or more of the following functions, namely a function of monitoring the state of the electrical storage cells, a function of controlling the discharging of all or some of the electrical storage cells, a function of controlling the charging of all or some of the electrical storage cells, and a function of balancing the charge of the electrical storage cells.

For example, the control system can be arranged so as to measure or estimate at least one parameter of each cell of the battery or of a group of cells, such as in particular the voltage at the terminals of each cell or each group of cells of the battery, or the temperature and/or the state of charge (SOC) and/or the state of health (SOH) of each cell or each group of cells of the battery. If required, the control system can have a memory wherein said parameter is stored and/or a communication unit capable of transmitting said parameter to an external terminal.

It can in particular be provided that the first printed circuit board has a first network of traces interconnecting the storage cells in order to collect the electrical power stored in each of the electrical storage cells to one or more pins of the first board edge connector or to one or more output terminals provided on the connection portion, and a second network of traces connecting each of the storage cells or each group of storage cells to a dedicated pin of the first board edge connector or to a dedicated output terminal provided on the connection portion. If required, the control system can be connected, by means of traces provided on the second printed circuit board, to dedicated complementary pins of the board edge connector or to dedicated complementary terminals provided on the connection portion, intended to come into contact with said dedicated terminals or with said dedicated pins when the connection portion is inserted into the board edge connector, the control system measuring or estimating said parameter via this second network of traces.

Also, for example, the control system can be arranged so as to permit or prohibit or control the charging and/or discharging of electrical storage cells as a function of said measured or estimated parameter.

For example, the control system can be arranged so as to actively or passively balance the charge of the storage cells of the battery, and in particular in order to charge or discharge one or more of the storage cells wherein the voltage, or the state of charge, differs substantially from that of the other storage cells of the battery such that this storage cell or these storage cells then has or have a voltage, or a state of charge, close to that of the other storage cells of the battery. For example, the first printed circuit board or the second printed circuit board can have one or more resistors which can be switched by the control system in order to allow discharging in this resistor or these resistors of the storage cells wherein the voltage, or the state of charge, is substantially higher than that of the other storage cells of the battery.

Advantageously, the first printed circuit board has a main portion wherein a plurality of notches are formed, each notch defining a tongue which is elastically deformable relative to the main portion, each first electrical connection element being disposed on one of the tongues of the first printed circuit board. These elastically deformable tongues allow solder-free contact to be maintained between the first electrical connection elements of the first printed circuit board and the contact terminals of the cells, in particular so that each of the cells can be replaced individually when used.

Advantageously, the first printed circuit board is arranged relative to the cells such that each cell creates on each tongue a mechanical force directed outward from the battery, and wherein each tongue of the first printed circuit board forms a spring having a restoring force directed toward the interior of the battery. If required, each notch of the first printed circuit board can be U-shaped. The tongue defined by each notch is thus connected to the main portion of the first printed circuit board by only one of its edges. If desired, the notches can be made by making cuts in the main portion of the first printed circuit board, prior to assembling the battery.

In one embodiment of the invention, each first connection element is provided with a bump made of an electrically conductive material which comes into contact with the contact terminal of one of the cells. This bump can, for example, be produced by depositing molten electrically conductive material, for example tin, at a termination of an electrical trace located on the tongue. This embodiment makes it possible to facilitate the contact between the electrical trace and the contact terminal when the contact terminal is flat.

In another embodiment of the invention, the contact terminal of each cell intended to come into contact with one of the first connection elements protrudes from the end face of the cell. In this case, the first connection element can be flat.

Advantageously, the battery comprises a spacer arranged to keep the cells apart from one another, the spacer and the first printed circuit board being arranged to hold the cells and the first printed circuit board such that each of the first electrical connection elements is located opposite one of the contact terminals of the cells. For example, the battery can have a single spacer. Preferably, the spacer is arranged so as to hold the cells in a matrix arrangement, side by side. If required, the first connection elements are distributed on the first printed circuit board in an arrangement corresponding to that of the cells.

Preferably, the spacer consists of a single plate having a plurality of primary through-passages, each cell being engaged through one of the primary through-passages. If required, each through-passage can have a profile which corresponds substantially, in shape and dimensions, to that of the cell which it receives.

Advantageously, the battery comprises a third printed circuit board disposed perpendicular to the end faces located on the other side of the cells, the third printed circuit board being provided with a plurality of second electrical connection elements, each of the second electrical connection elements being located opposite one of the contact terminals of the cells. If required, one of the second and third printed circuit boards can have a second board edge connector and the other of the second and third printed circuit boards can have a connection portion that inserts into said second board edge connector.

Preferably, the first and second board edge connectors and the connection portions can be arranged such that the first printed circuit board and the third printed circuit board extend parallel to each other, when these connection portions are inserted into the first and second board edge connectors.

In one embodiment of the invention, the second printed circuit board has the first and second board edge connectors and each of the first and third printed circuit boards has a connection portion that inserts into one of the first and second board edge connectors. For example, the first and second board edge connectors can be arranged parallel to one another on the same surface of the second printed circuit board, in particular at two opposite edges of said surface. If required, the second printed circuit board can abut a rim of each of the first and third printed circuit boards.

In a further embodiment of the invention, the first printed circuit board has the first board edge connector, the third printed circuit board has the second board edge connector, and the second printed circuit board has two connection portions that each insert into one of the first and second board edge connectors. For example, the connection portions can each protrude from opposite edges of the second printed circuit board. If required, the second printed circuit board can be placed between opposing surfaces of the first and third printed circuit boards.

Advantageously, said printed circuit board having the first board edge connector has a locking member arranged perpendicular to this board edge connector and said printed circuit board having the connection portion has a complementary element arranged perpendicular to the connection portion, the locking member and the complementary element being arranged so as to interact with each other so as to hold the connection portion in the board edge connector.

Also advantageously, the locking member has a base via which it is mounted on said printed circuit board having the first board edge connector and a part movably mounted on the base. If required, said part is able to assume a locking configuration wherein it interacts with the complementary element so as to oppose withdrawal of the connection portion from the board edge connector, and an unlocking configuration wherein it permits withdrawal of the connection portion from the board edge connector.

For example, the complementary element can have an oblong hole formed in the connection portion and the locking member in order to have a catch pivotably mounted on a base, the catch being capable of pivoting between the unlocking configuration wherein the protruding part of the catch is aligned with the oblong hole, and can therefore pass through it in order to allow withdrawal of the connection portion from the board edge connector, and the locking configuration wherein the protruding part of the catch is offset relative to the oblong hole and abuts the connection portion so as thus to oppose withdrawal of the connection portion from the board edge connector.

If desired, the battery can have an output connector intended for charging and/or discharging the electrical storage cells. If required, the output connector can be arranged on the first printed circuit board and the first printed circuit board can have a set of electrical traces connecting the first electrical connection elements to one or more connection terminals provided on the connection portion or to one or more connection pins provided on the first board edge connector and at least one further electrical trace connecting a further connection terminal provided on the connection portion, or a further connection pin provided on the first board edge connector, to the output connector.

Also advantageously, the battery has a fastener arranged so as to hold the first printed circuit board against the third printed circuit board. If required, the fastener can be arranged so as to exert a force on each of the first and third printed circuit boards directed toward the interior of the battery. The printed circuit boards are thus stressed such that the cells create a mechanical force on the tongues.

For example, the fastener can comprise one or more connecting rods attached to the first printed circuit board, and optionally to the third printed circuit board. If required, each printed circuit board has one or more orifices, and each connecting rod is intended to be engaged through one of these orifices. Advantageously, the spacer can have one or more secondary through-passages, each disposed opposite one of the orifices of the first and/or third printed circuit boards, each connecting rod being intended to be engaged through one of the secondary through-passages.

Alternatively or cumulatively, the fastener can have a housing to which the first and third printed circuit boards are attached. If required, the housing can have protuberances, each arranged opposite a zone of the main portion of the first and/or third printed circuit board located perpendicular to the tongues, so as to exert a force, directed toward the interior of the battery, on this first and/or third printed circuit board.

Advantageously, the battery has a housing arranged so as to receive the plurality of cells and the first printed circuit board, the housing having a means of assembly to an element of a vehicle, in particular to a chassis of an electric vehicle or to a frame of a bicycle.

The present invention is now described using examples, which are only illustrative and in no way limit the scope of the invention, and from the accompanying illustrations, wherein:

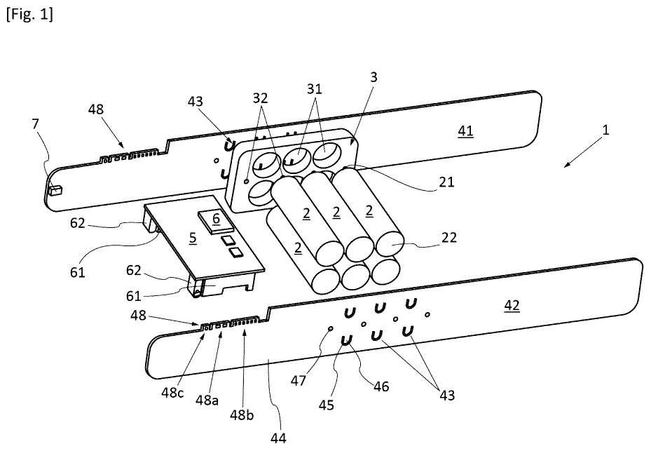

FIG. 1 is, partially and schematically, an exploded view of a battery according to a first embodiment of the invention;

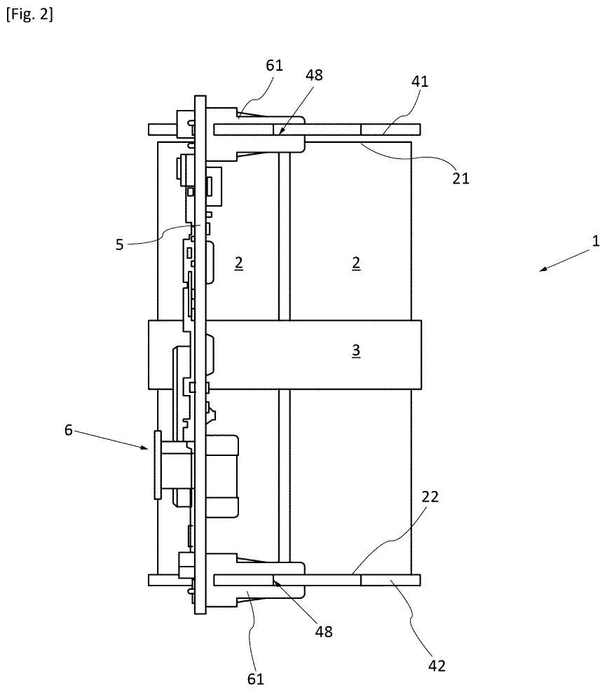

FIG. 2 is, schematically and partially, a front view of a first printed circuit board of the battery of FIG. 1;

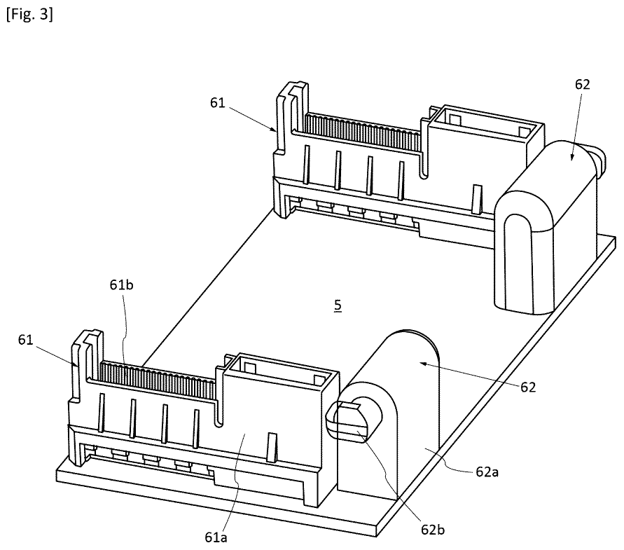

FIG. 3 is, schematically and partially, a perspective view of a second printed circuit board of the battery of FIG. 1;

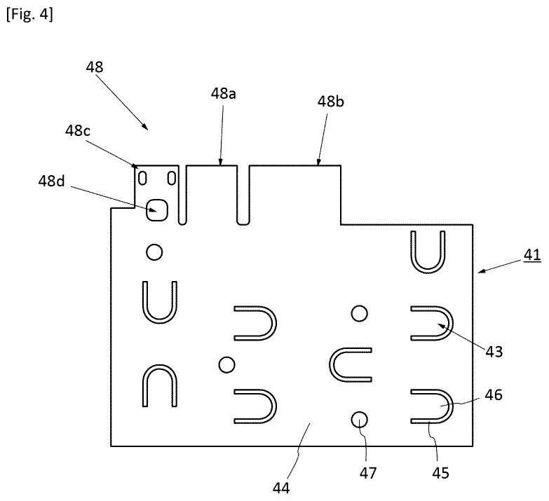

FIG. 4 is, schematically and partially, a side view of the battery of FIG. 1 after assembly; and

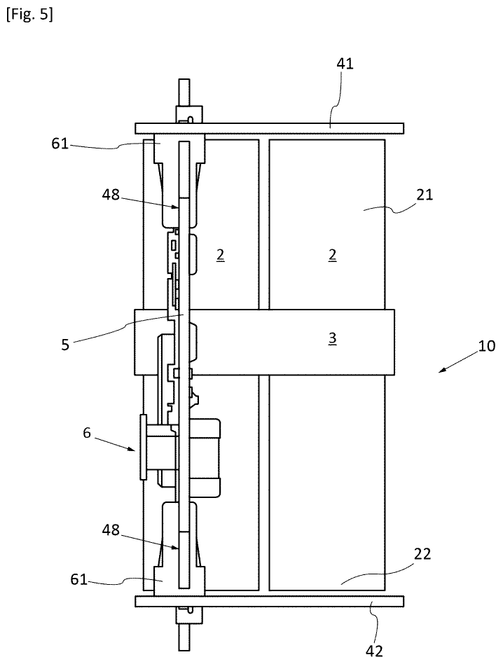

FIG. 5 is, schematically and partially, a side view of an assembled battery according to a second embodiment of the invention.

In the following description, identical elements, by structure or function, appearing in different figures retain, unless otherwise specified, the same references.

An exploded view of an electric battery 1 of an electric vehicle according to a first embodiment of the invention is shown in [FIG. 1]. Also shown in [FIG. 2] is a cross section of the battery 1 of [FIG. 1] when assembled.

The battery 1 has a plurality of electrical storage cells 2, each cell 2 being a lithium-ion-type accumulator of cylindrical shape and having an upper end face 21 and a lower end face 22, each provided with a flat contact terminal.

The cells 2 are disposed side by side in a matrix arrangement. In the example described, the battery 1 has six cells 2 distributed in two superposed lines of three cells 2, it being understood that a different number and/or distribution of cells can be envisaged.

The battery 1 has a single spacer plate 3 provided with a plurality of primary cylindrical through-passages 31 distributed over the plate in a matrix fashion and the dimensions of which correspond to those of the cells 2. Each cell 2 is engaged in one of the passages 31 such that the spacer plate 3 keeps the cells 2 apart from one another.

The battery 1 has a first printed circuit board 41, disposed above the cells 2 on the side of the upper end faces 21, a second printed circuit board 5, and a third printed circuit board 42, disposed below the cells 2 on the side of the lower end faces 22.

Each of the first and third printed circuit boards 41 and 42 has a plurality of electrical connection elements 43 which are interconnected by electrical traces. Thanks to the spacer plate 3, the cells 2 are held in such a way that each of their contact terminals faces one of the electrical connection elements 43 of the printed circuit boards 41 and 42.

Each of the first and third printed circuit boards 41 and 42 has a main portion 44 wherein U-shaped notches 45 have been cut. Each of the notches 45 defines a tongue 46, connected to the main portion by only one of its edges. Each tongue 46 is thus elastically deformable relative to the main portion 44 and forms a spring having a restoring force which returns the tongue 46 toward the main portion 44 when a force is exerted on this tongue 46.

In the example of [FIG. 1] and [FIG. 2], each electrical connection element 43 is formed on one of the tongues 46 of the printed circuit boards 41 and 42, and for this purpose has a tin bump disposed at a termination of an electrical trace extending over this tongue 46.

In addition, the battery 1 has a plurality of connecting rods (not shown) which are intended to be inserted between the printed circuit boards 41 and 42 by being engaged in secondary through-passages 32 of the spacer plate 3 which are provided between the primary through-passages 31. Orifices 47 are formed in the main portions 44 of the printed circuit boards 41 and 42, opposite the primary through-passages 31, such that these connecting rods can pass through them. Each connecting rod is equipped with tightening members at its ends, for example of the washer and bolt type, such that the first and third printed circuit boards 41 and 42 can be tightened in the direction of each other.

In order to assemble the battery 1, the cells 2 are inserted into the primary through-passages 31 of the spacer plate 3 and the connecting rods are inserted into the secondary through-passages 32. The first and third printed circuit boards 41 and 42 are disposed on either side of the assembled cells 2 such that the contact terminals 23 face the connection elements 43. The first and third printed circuit boards 41 and 42 are tightened toward each other by means of the tightening members of the connecting rods in order to generate a force on the tongues 46 toward the interior of the battery. This force thus holds the cells 2 in position between the first and third printed circuit boards 41 and 42. In return, each of the cells 2 exerts, at its upper end face 21 and respectively its lower end face 22, a force on the tongue 46 of the first printed circuit board 41 and respectively of the third printed circuit board 42, opposite which it is disposed. Each tongue 46 is thus elastically deformed by one of the cells 2 by being pushed outward from the battery 1.

As the force created by the cell 2 on each tongue 46 is oriented outward from the battery 1, the restoring force of the spring formed by this tongue 46 is therefore exerted toward the interior of the battery 1, which maintains contact between the bump of the connection element 43 located on this tongue 46 and the flat contact terminal of the cell 2. This then ensures that the contact can be maintained between the connection element 43 and the contact terminal. Furthermore, the assembly of the battery 1, and the replacement of the cells 2 when used, can be carried out simply and quickly without a soldering or welding operation.

The second printed circuit board 5 supports a control system 6 for the cells 2, also known as a BMS.

In order to be able to connect the second printed circuit board 5 to the first and third printed circuit boards 41 and 42, the second printed circuit board 5 has first and second board edge connectors 61, arranged on the same surface of the second printed circuit board 5 opposite the surface supporting the control system 6. This surface is shown in [FIG. 3].

The connectors 61 are arranged on the second printed circuit board 5 parallel to each other at two opposite edges of the second printed circuit board 5. These connectors 61 are identical and each connector has a so-called power portion 61a and a so-called signal portion 61b, each portion 61a and 61b being equipped with a plurality of pairs of connection pins, the pins of the same pair facing each other and each pin of a pair each forming a spring, the restoring force of which is oriented toward the other pin of this pair.

The second printed circuit board 5 also has two locking members 62, each arranged perpendicular to one of the connectors 61. Each locking member 62 has a base 62a, mounted on the board 5, and a part 62b equipped with a catch and mounted on a side wall of the base 62a extending from the side of the edge of the board 5 perpendicular to which the base 62a and the adjacent connector 61 are mounted. Furthermore, the part 62b is pivotably mounted on the base 62a. It will be noted that the locking members 62 are not shown in [FIG. 2].

In addition, each of the first and third printed circuit boards 41 and 42 has a connection portion 48 protruding from its main portion 44 from one of its edges. The connection portions 48 of the first and third printed circuit boards 41 and 42 are identical and have been shown in [FIG. 4].

Each connection portion 48 has a so-called power plug 48a and a so-called signal plug 48b, these plugs being equipped with connection terminals (not shown in [FIG. 4]). Each connection portion 48 is thus intended to be inserted into a board edge connector 61 in order to mechanically and electrically connect the printed circuit boards 41, 42, and 5 to one another. When a connection portion 48 is inserted into a connector 61, the power plug 48a penetrates the power portion 61a and the signal plug 48b penetrates the signal portion 61b, each plug spreading the pairs of connection pins of the portion which it penetrates, and these pins being held in contact with the connection terminals by virtue of their restoring force.

It will be noted that the arrangement of the board edge connectors 61 on the second printed circuit board and of the connection portions 48 on the first and third printed circuit boards 41 and 42 orients the first and third printed circuit boards 41 and 42 in such a way that they are parallel to each other and perpendicular to the second printed circuit board 5 when the connection portions 48 are inserted into the board edge connectors 61.

Each connection portion 48 furthermore has a plug 48c, forming a complementary element of the locking member 62 adjacent to the board edge connector 61 into which it is inserted. This plug 48c has an oblong hole 48d.

When a connection portion 48 is inserted into a board edge connector 61, the catch 62d is positioned in an unlocking configuration wherein the protruding part of the catch 62d is aligned with the oblong hole 48d. The catch 62d can therefore pass through the catch 62d. Once the connection portion 48 has been inserted, the catch 62d can be pivoted toward a locking configuration wherein the protruding part of the catch 62d is offset relative to the oblong hole 48d. The catch 62d thus abuts the plug 48c and thus opposes the withdrawal of the connection portion 48 from the board edge connector 61.

This control system 6 is able to perform functions of monitoring the state of the cells 2, controlling the charging and discharging of the cells 2, and balancing the charging of the cells 2.

To this end, each of the first and third printed circuit boards 41 and 42 has a first network of electrical traces (not shown) interconnecting the electrical connection elements 43, and therefore the cells 2, to the connection terminals of the power plug 48a. In addition, each of the first and third printed circuit boards 41 and 42 has a second network of electrical traces (not shown) connecting each of the electrical connection elements 43, and therefore one of the cells 2, to one of the connection terminals of the signal plug 48b.

The control system 6 is connected, via electrical traces of the second printed circuit board 5, to the connection pins of the power portion 61a and the signal portion 61b of the connectors 61. In this way, the control system 6 can measure or estimate a parameter of each cell 2 of the battery 1, such as the voltage at the terminals of each cell 2, via the connection pins of the signal portion 61b, and monitor the electrical power delivered to the cells 2 when they are being charged or the electrical power delivered by the cells 2 when they are being discharged, via the connection pins of the power portion 61a.

It will be noted that the first printed circuit board 41 has an output connector 7 connected to the connection terminals of the power plug 48a of this printed circuit board 41, this connector being able to receive electrical power delivered by an external electrical power source and relaying this power to the second printed circuit board 5 in order to charge the cells 2, via the board edge connectors 61 and the connection portions 48, or being able to receive electrical power delivered by the cells 2 to the second printed circuit board 5, via the board edge connectors 61 and the connection portions 48, in order to supply or electrically charge an external electronic device.

It can in particular be provided that a switch is present on the second printed circuit board 5, controlled by the control system 6 and allowing charging or discharging of the cells 2 to be interrupted, depending on the parameters of the cells 2 which are measured or estimated by the control system 6, or on the electrical charging or discharging power monitored by the control system 6.

It can also be provided that a resistor or a set of resistors is present on the second printed circuit board 5, which can be switched by the control system 6 in order to perform a passive balancing function of the cells 2.

It can also be provided that one or more thermistors is or are present on the first and/or third printed circuit board 41 and 42, allowing the control system 6 to monitor the temperature of the cells 2.

[FIG. 5] shows a cross section of a battery 10 according to a second embodiment of the invention.

In contrast to the first embodiment of the invention in [FIG. 1] to [FIG. 4], the board edge connectors 61 are arranged on the first and third printed circuit boards 41 and 42, and the connection portions 48 are arranged on two opposite edges of the second printed circuit board 5. Once the connection portions 48 have been inserted into the board edge connectors 61, the second printed circuit board 5 thus extends between the first and third printed circuit boards 41 and 42.

The preceding description clearly explains how the invention makes it possible to achieve its objectives, and in particular by proposing a battery, the cells of which are interconnected via a first printed circuit board, the management or control system of which for these cells is arranged on a second printed circuit board, the first and second printed circuit boards being connected to each other by a board edge connector. Thus, as can be seen from the description, the cells and the control system are provided on two separate boards which can be assembled or disassembled quickly and simply, allowing the control system or the cells to be replaced independently.

In any case, the invention is not limited to the embodiments specifically described in this document, and extends in particular to any equivalent means and to any technically operative combination of these means. In particular, other notch and tongue profiles, or even other printed circuit board fastening methods than those described, can be provided. It can in particular be provided that the connection elements of the first and/or third printed circuit board are flat and that each contact terminal of each cell protrudes from the end face of the cell. It can in particular also be provided that the first and third printed circuit boards are forced toward each other by means of an element other than connecting rods, for example by means of a housing equipped with ribs or protuberances exerting a force on these printed circuit boards between the connection elements. A connection topology of the control system for the cells which is not centralized but is also modular can also be provided, wherein groups of cells are individually connected to the control system.

1. Electric battery (1, 10), comprising:
a. a plurality of electrical storage cells (2), each cell having end faces (21, 22) located on opposite sides of the cell, each end face being provided with a contact terminal;
b. at least one first printed circuit board (41) disposed perpendicular to the end faces located on one of the sides of the cells, the printed circuit board being provided with a plurality of first electrical connection elements (43), each of the first electrical connection elements being located opposite one of the contact terminals of the cells;
c. a second printed circuit board (5) supporting a control system (6) for the electrical storage cells;
characterized in that one of the first and second printed circuit boards has a first board edge connector (61) and in that the other of the first and second printed circuit boards has a connection portion that inserts into said first board edge connector.

2. The electric battery (1, 10) according to claim 1, wherein the first printed circuit board has a main portion wherein a plurality of notches (45) are formed, each notch defining a tongue (46) which is elastically deformable relative to the main portion, each first electrical connection element being disposed on one of the tongues of the first printed circuit board.

3. The electric battery (1, 10) according to claim 2, wherein the first printed circuit board (41) is arranged relative to the cells (2) such that each cell creates on each tongue (46) a mechanical force directed outward from the battery, and wherein each tongue of the first printed circuit board forms a spring having a restoring force directed toward the interior of the battery.

4. The electric battery (1, 10) according to claim 1, any characterized in that it comprises a third printed circuit board (42) disposed perpendicular to the end faces (21, 22) located on the other side of the cells (2), the third printed circuit board being provided with a plurality of second electrical connection elements (43), each of the second electrical connection elements being located opposite one of the contact terminals of the cells, and in that one of the second and third printed circuit boards (5, 42) has a second board edge connector (61), and in that the other of the second and third printed circuit boards has a connection portion (48) that inserts into said second board edge connector.

5. The electric battery (1) according to claim 4, characterized in that the second printed circuit board (5) has the first and second board edge connectors (61) and in that each of the first and third printed circuit boards (41, 42) has a connection portion (48) that inserts into one of the first and second board edge connectors.

6. The electric battery (10) according to claim 4, characterized in that the first printed circuit board (41) has the first board edge connector (61), in that the third printed circuit board (42) has the second board edge connector (61), and in that the second printed circuit board (5) has two connection portions (48) that each insert into one of the first and second board edge connectors.

7. The electric battery (1, 10) according to claim 1, any characterized in that said printed circuit board (41, 42, 5) having the first board edge connector (61) has a locking member (62) arranged perpendicular to the provided board edge connector and in that said printed circuit board (41, 42, 5) having the connection portion (48) has a complementary element (48c) arranged perpendicular to the connection portion, the locking member and the complementary element being arranged so as to interact with each other so as to hold the connection portion in the board edge connector.

8. The electric battery (1, 10) according to claim 7, wherein the locking member (62) has a base (62a) via which it is mounted on said printed circuit board (41, 42, 5) having the first board edge connector (61) and a part (62b) mounted movably on the base and able to assume a locking configuration wherein it interacts with the complementary element (48c) so as to oppose withdrawal of the connection portion (48) from the board edge connector and an unlocking configuration wherein it allows withdrawal of the connection portion from the board edge connector.

9. The electric battery (1, 10) according to claim 1, any characterized in that it comprises an output connector (7) intended for charging and/or discharging the electrical storage cells (2), in that the output connector is arranged on the first printed circuit board (41), and in that the first printed circuit board has a set of electrical traces connecting the first electrical connection elements (43) to one or more connection terminals provided on the connection portion (48) or to one or more connection pins provided on the first board edge connector (61), and at least one further electrical trace connecting a further connection terminal provided on the connection portion or a further connection pin provided on the first board edge connector to the output connector.
